(19) United States
(12) Patent Application Publication
(10) Pub. No.: US 2026/0068454 A1
(43) Pub. Date: Mar. 5, 2026

(54) DISPLAY DEVICE

(71) Applicant: Samsung Display Co., Ltd., Yongin-Si (KR)

(72) Inventors: Eun Byul KIM, Yongin-si (KR); Han Bum KWON, Yongin-si (KR); Young Min AHN, Yongin-si (KR)

(21) Appl. No.: 19/083,451

(22) Filed: Mar. 19, 2025

(30) Foreign Application Priority Data
Sep. 5, 2024 (KR) 10-2024-0120591

(51) Int. Cl. H10K 59/131; H01L 23/498; H10K 59/95

(52) U.S. Cl. CPC H10K 59/131; H10K 59/95

(57) ABSTRACT

The present disclosure relates to a display device, and more particularly, to a display device capable of minimizing damage to a circuit board and a display panel. According to an aspect of the present disclosure, there is provided a display device including: a display panel having an edge, a pad, and a dummy area between the edge and the pad; a first circuit board connected to a pad of the display panel and overlapping an edge of the display panel; and a dummy protrusion pattern disposed in the dummy area and overlapping the first circuit board.

### CROSS-REFERENCE TO RELATED APPLICATION

This application claims the benefit of Korean Patent Application No. 10-2024-0120591 filed on Sep. 5, 2024 in the Korean Intellectual Property Office, the disclosure of which is incorporated herein in its entirety by reference.

### BACKGROUND

### 1. Field

The present disclosure relates to a display device, and more particularly, to a display device capable of minimizing damage of a circuit board and a display panel.

### 2. Description of the Related Art

Organic light emitting diode (OLED) displays have self-luminous characteristics and, unlike liquid crystal displays, do not require a separate light source. Not needing a separate light source reduces an OLED display's thickness and weight. In addition, OLED displays are attracting attention as next-generation displays for televisions, monitors, and portable electronic devices due to their desirable characteristics such as low power consumption, high luminance, and high response speed.

### SUMMARY

Aspects of the present disclosure provide a display device capable of minimizing damage of a circuit board and a display panel.

According to an aspect of the present disclosure, there is provided a display device including: a display panel having an edge, a pad, and a dummy area between the edge and the pad; a first circuit board connected to the pad of the display panel and overlapping an edge of the display panel; and a dummy protrusion pattern disposed in the dummy area and overlapping the first circuit board.

According to an aspect of the present disclosure, there is provided an electronic device including a memory, a processor executing an application stored in the memory, and a display module including: a display panel having an edge, a pad, and a dummy area between the edge and the pad; a first circuit board connected to the pad of the display panel and overlapping an edge of the display panel; and a dummy protrusion pattern disposed in the dummy area and overlapping the first circuit board.

According to a display device of one embodiment, a dummy protrusion pattern may be disposed between an edge of a display panel and a circuit board. Accordingly, during a process of attaching the display panel and the circuit board, a gap may be maintained between the edge of the display panel and the circuit board to prevent damage to the circuit board and the display panel. Such damage may be due to the circuit board contacting the display panel.

Aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to one embodiment;

FIG. 2 is an enlarged view of area A1 of FIG. 1;

FIG. 3 is an enlarged view of area A2 of FIG. 2;

FIG. 4 is a cross-sectional view taken along line I-I′ of FIG. 3;

FIG. 5 is an enlarged view of area A3 of FIG. 4;

FIG. 6 is a cross-sectional view of a display device according to another embodiment; and

FIG. 7 is a cross-sectional view of a display device according to still another embodiment.

FIG. 8 is a block diagram of an electronic device according to one embodiment.

FIGS. 9, 10, and 11 are schematic diagrams of electronic devices according to various embodiments.

### DETAILED DESCRIPTION

The inventive concept will now be described more fully hereinafter with reference to the accompanying drawings, in which preferred embodiments of the disclosure are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may be present. The same reference numbers indicate the same components throughout the specification. In the attached figures, the thickness of layers and regions is exaggerated for clarity.

Although the terms “first”, “second”, etc. may be used herein to describe various elements, these elements, should not be limited to any order or priority by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or as a whole. As will be clearly appreciated by those skilled in the art, technically various interactions and operations are possible. Various embodiments can be practiced individually or in combination.

Hereinafter, embodiments will be described in detail with reference to the accompanying drawings.

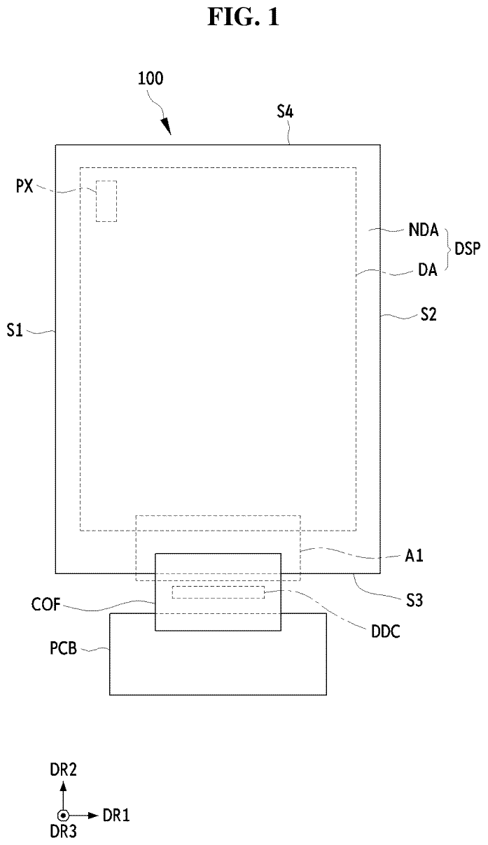

FIG. 1 is a plan view of a display device 100 according to one embodiment.

Referring to FIG. 1, the display device 100 is a device for displaying moving images or still images. The display device 100 may be used to display images in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices. These are presented as examples, and the display device 100 can also be employed in other electronic devices.

The display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode. However, the present disclosure is not limited thereto. For example, the display device 100 may also be a display device of a type other than a light emitting display device. Embodiments in which the display device 100 is a light emitting display device (e.g., an organic light emitting display device) will be disclosed below.

The display device 100 may include a display panel DSP, a first circuit board COF, a second circuit board PCB, and a driver circuit DDC (hereinafter., a data driver circuit DDC).

The display panel DSP may be provided as a rigid panel that is substantially not deformed or may be provided as a flexible panel that can be deformed, for example, folded, bent, or rolled in at least a portion. The display panel DSP may be provided to the display device 100 in an unbent state or may be provided to the display device 100 in a bent state in some sections.

The display panel DSP may include a display area DA and a non-display area NDA.

A plurality of pixels PX may be disposed in the display area DA. The pixels PX may display an image. In addition, a plurality of gate lines and a plurality of emission lines connected to the pixels PX may be disposed in the display area DA. The display area DA may have various shapes according to embodiments. For example, the display area DA may have a quadrilateral shape, a polygonal shape other than the quadrilateral shape, a circular shape, an oval shape, an irregular shape, or other shapes. In an embodiment, the display area DA may have a shape that is similar to the shape of the display panel DSP. As used herein, “similar” shapes have substantially the same proportions of parts but may be different in size.

The non-display area NDA may be disposed around the display area DA. In an embodiment, the non-display area NDA may surround the display area DA. A gate driver and an emission driver for driving the pixels PX may be disposed in the non-display area NDA of the display panel DSP. The gate driver may be connected to the gate lines, and the emission driver may be connected to the emission lines. Gate signals from the gate driver may be supplied to the pixels PX through the gate lines, and emission signals from the emission driver may be supplied to the pixels PX through the emission lines.

The first circuit board COF may be connected to the display panel DSP and the second circuit board PCB. For example, a side of the first circuit board COF may be electrically connected to the non-display area NDA of the display panel DSP, and the other side of the first circuit board COF may be electrically connected to the second circuit board PCB. A first side S1 and a second side S2 of the display panel DSP may face each other in a first direction DR1, and a third side S3 and a fourth side S4 of the display panel DSP may face each other in a second direction DR2. The first circuit board COF may overlap the third side S3. Here, the first side S1 (or the second side S2) may have a longer length than the third side S3 (or the fourth side S4). However, the present disclosure is not limited thereto, and the length of each of the first side S1, the second side S2, the third side S3, and the fourth side S4 can be variously modified. The first circuit board COF may be, but is not limited to, a flexible printed circuit board, a printed circuit board, or a flexible film such as chip on film. A data driver circuit DDC may be disposed on the first circuit board COF.

The data driver circuit DDC may be connected to the non-display area NDA of the display panel DSP through the first circuit board COF. The data driver circuit DDC, for example, may include an integrated circuit.

A timing controller and a power supply unit may be disposed on the second circuit board PCB. The second circuit board PCB may be, but is not limited to, a flexible printed circuit board, a printed circuit board, or a flexible film such as chip on film.

The power supply unit may supply power voltages to the pixels PX, the gate driver, the emission driver, and the data driver circuit DDC. The timing controller may control the operations of the gate driver, the emission driver, and the data driver circuit DDC.

Through the first circuit board COF, a gate timing control signal, an emission timing control signal, a gate clock signal, an emission clock signal, a gate start signal, an emission start signal, a high-potential voltage, and a low-potential voltage from the timing controller disposed on the second circuit board FPCB may be supplied to the gate driver and the emission driver. For example, the gate timing control signal, the gate clock signal, the gate start signal, the high-potential voltage and the low-potential voltage may be supplied to the gate driver, and the emission timing control signal, the emission clock signal, the emission start signal, the high-potential voltage and the low-potential voltage may be supplied to the emission driver. In addition, power signals from the power supply unit may be supplied to the gate driver, the emission driver, and the pixels PX through the first circuit board COF. The power signals may include, for example, a driving voltage, a common voltage, an initialization voltage, and a bias voltage.

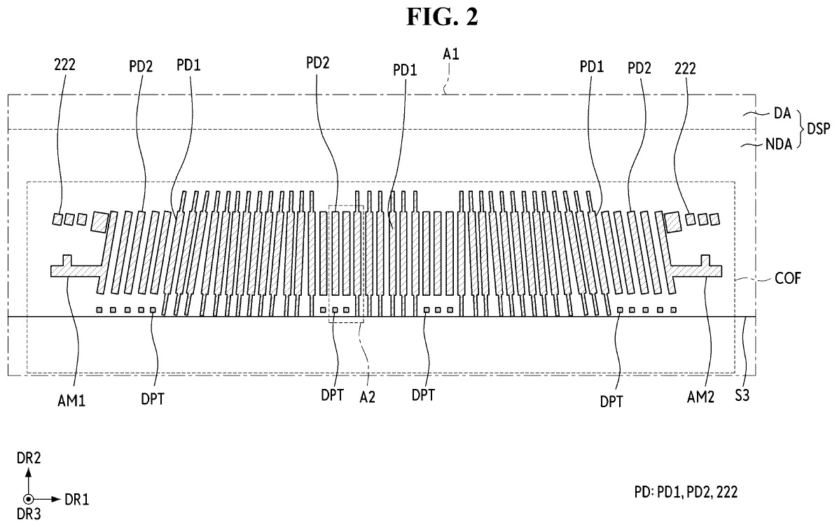

FIG. 2 is an enlarged view of area A1 of FIG. 1.

As illustrated in FIG. 2, a plurality of pads PD may be disposed in the non-display area NDA of the display panel DSP. For example, the pads PD may be disposed close to an edge (e.g., the third side S3) of the display panel DSP. Here, the pads PD may be arranged along the third side S3. For example, the pads PD may be arranged along the first direction DR1.

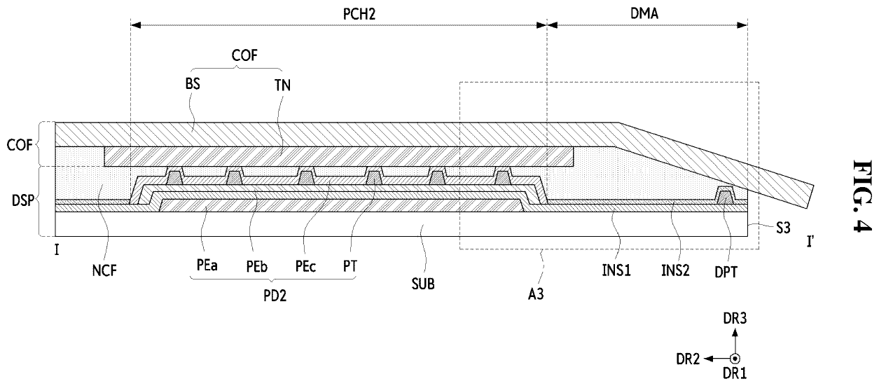

The pads PD of the display panel DSP may be connected to a plurality of terminals (or bumps; e.g., TN of FIG. 4) of the first circuit board COF.

At least one of the pads PD of the display panel DSP may have a diagonally inclined shape. Here, the pad PD disposed at the center of the display panel DSP (or the display area DA) may extend parallel to the first side S1. A set of pads PD in the center region of the display panel DSP may be defined as a center pad. The pads PD disposed between the center pad and the first side S1 of the display panel DSP may be inclined such that the end that is farthest from the third side S3 tilts toward the second side S2. The degree of tilt increases as the pads PD are disposed farther away from the center pad. The pads PD disposed between the center pad and the second side S2 of the display panel DSP may be inclined such that the end that is farthest from the third side S3 tilts toward the first side S1. The farther from the center pad a pad PD is, the greater the degree of tilt toward the first side S1.

The pad PD that is closest to the first side S1 of the display panel DSP is defined as a first outermost pad, and the pad PD that is closest to the second side S2 of the display panel DSP is defined as a second outermost pad. A first align mark AM1 of the display panel DSP may extend from the outer side of the first outermost pad, and a second align mark AM2 of the display panel DSP may extend from the outer side of the second outermost pad. Here, the first align mark AM1 and the first outermost pad may be integrally formed, and the second align mark AM2 and the second outermost pad may be integrally formed. The terminals of the first circuit board COF may be disposed in the same shape as the pads PD of the display panel DSP described above. For example, at least one of the plurality of terminals TN of the first circuit board COF may have a diagonally inclined shape.

As described above, as the pads PD of the display panel DSP and the corresponding terminals TN of the first circuit board COF are disposed in the diagonal direction, even if the pads PD and first terminals TN1 are misaligned in the first direction DR1, the first circuit board COF may be moved in the second direction DR2 to place the pads PD in contact with the corresponding one of the terminals TN in spite of the initial misalignment.

The plurality of pads PD may include a plurality of first pads PD1, a plurality of second pads PD2, and inspection pads 222.

The first pads PD1 may be connected to signal lines of the display panel DSP and the terminals TN of the first circuit board COF. The second pads PD2 may be dummy pads not connected to the signal lines of the display panel DSP. In the embodiment shown in FIG. 2, the second pads PD2 are shorter than the first pads PD1. The inspection pads 222 may be pads for applying an inspection signal to the display panel DSP.

At one edge of the display panel DSP, at least one dummy protrusion pattern DPT may be disposed. For example, the dummy protrusion pattern DPT of the display panel DSP may be disposed at the edge of the display panel DSP to be adjacent to one side (e.g., the third side S3) of the display panel DSP overlapping the first circuit board COF. At this time, the dummy protrusion patterns DPT may overlap the first circuit board COF. For example, the dummy protrusion patterns DPT and the first circuit board COF may overlap in a third direction DR3.

The dummy protrusion pattern DPT may be disposed between the pad PD and an edge of the display panel DSP, such as the third side S3 of the display panel DSP. For example, in plan view, the dummy protrusion patterns DPT may be disposed between the pads PD and the third side S3. According to an embodiment illustrated in FIG. 2, the dummy protrusion patterns DPT may be disposed between the second pads PD2 and the third side S3 of the display panel DSP. However, the present disclosure is not limited to the embodiment shown, and in plan view, the dummy protrusion patterns DPT may be disposed between the first pads PD1 and the third side S3 of the display panel DSP.

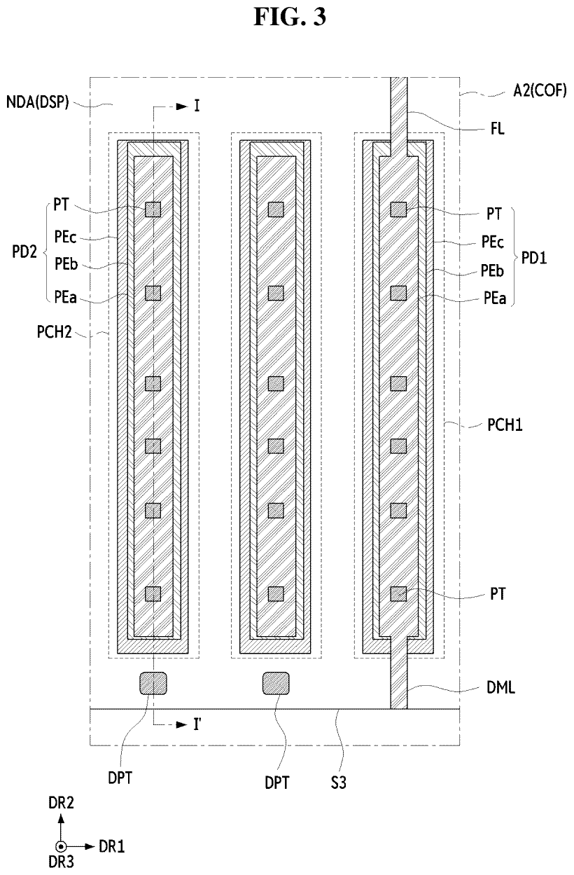

FIG. 3 is an enlarged view of area A2 of FIG. 2, and FIG. 4 is a cross-sectional view taken along line I-I′ of FIG. 3.

As illustrated in FIG. 3, the first pad PD1 may be exposed to the outside through a first pad contact hole PCH1. For example, the first pad PD1 may be defined by the first pad contact hole PCH1 formed in a second insulating layer INS2 (see FIG. 4) to be described later. The first pad PD1 may be connected to a fan-out line FL and a dummy line DML. For example, the first pad PD1 may include a first pad electrode PEa, a second pad electrode PEb, a third pad electrode PEc, and a protrusion pattern PT. The first pad electrode PEa of the first pad PD1 may be connected to the fan-out line FL and the dummy line DML. The fan-out line FL, for example, may be connected to the data line. The dummy line DML, the first pad electrode PEa of the first pad PD1, and the fan-out line FL may be integrally formed. Meanwhile, the dummy line DML may be a part of an inspection line for applying an inspection signal during the manufacturing process of the display device 100. For example, after completing the inspection process of the display panel DSP for an inspection line, the inspection line may be cut in a scribing process of the display panel DSP, and the dummy line DML described above may be a part of the cut inspection line. For example, in the scribing process, the display panel DSP may be cut along the third side S3.

As illustrated in FIGS. 3 and 4, the second pad PD2 may be exposed to the outside through a second pad contact hole PCH2. For example, the second pad PD2 may be defined by the second pad contact hole PCH2 formed in the second insulating layer INS2. The second pad PD2 may include a first pad electrode PEa, a second pad electrode PEb, a third pad electrode PEc, and a protrusion pattern PT.

The first pad electrode PEa of the second pad PD2 may be disposed on a substrate SUB of the display panel DSP. Each of the first pad electrodes PEa of the second pad PD2 may include a conductive material including molybdenum (Mo), aluminum (Al), copper (Cu), titanium (Ti), etc. and may be formed as a multilayer or single layer including the above materials. A first insulating layer INS1 may be disposed on the first pad electrode PEa.

The second pad electrode PEb of the second pad PD2 may be disposed on the first insulating layer INS1 and overlap the first pad electrode PEa of the second pad PD2. Each of the second pad electrodes PEb may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may be a single layer or multilayer of the above materials.

The protrusion pattern PT of the second pad PD2 may be disposed on the second pad electrode PEb. The protrusion pattern PT may be in contact (or direct contact) with the second pad electrode PEb. For example, each of the protrusion pattern PT may include a polymer-based material. Examples of the polymer-based material may include acrylic resin, epoxy resin, polyimide, and polyethylene.

The third pad electrode PEc of the second pad PD2 may be disposed on the protrusion pattern PT of the second pad PD2 and the second pad electrode PEb of the second pad PD2. The third pad electrode PEc of the second pad PD2 may be in contact (or in direct contact) with the protrusion pattern PT and the second pad electrode PEb. Each of the third pad electrodes PEc may include a conductive material including molybdenum (Mo), aluminum (Al), copper (Cu), titanium (Ti), etc. and may be formed as a multilayer or single layer including the above materials. As the plurality of protrusion patterns PT are disposed along a longitudinal direction (e.g., the second direction DR2) of each second pad PD2, the third pad electrode PEc on each of the plurality of protrusion patterns PT may have an uneven shape as in the example illustrated in FIG. 4. For example, the surface of each of the third pad electrode PEc may be elevated along a third direction DR3 and recessed along a reverse direction (hereinafter, referred to as a reverse third direction) of the third direction DR3 between the elevated portions. Specifically, the third pad electrode PEc may be elevated in the third direction DR3 by being disposed on the protrusion patterns PT and may be recessed in the third reverse direction between the adjacent protrusion patterns PT. Here, the elevated portions of the third pad electrode PEc may be in contact (or in direct contact) with the terminal of the first circuit board COF. Through such contact, the third pad electrode PEc of the second pad PD2 and the terminal TN of the first circuit board COF may be electrically connected. Here, the first circuit board COF, for example, may include a base portion BS (or a base film) and a plurality of terminals TN. The terminal TN of the first circuit board COF may be disposed between the base portion BS and the second pad PD2 (e.g., the third pad electrode PEc of the second pad PD2), and the terminal TN of the first circuit board COF may overlap the plurality of protrusion patterns PT of the second pad PD2. The base portion BS of the first circuit board COF, for example, may be formed of a material containing polyimide.

The second insulating layer INS2 may be disposed on the first insulating layer INS1. The second insulating layer INS2 may be in contact (or in direct contact) with the first insulating layer INS1. In addition, the second insulating layer INS2 may be disposed on the dummy protrusion pattern DPT. The second insulating layer INS2 on the dummy protrusion pattern DPT may be in contact with the base portion BS of the first circuit board COF. The second insulating layer INS2 may have the second pad contact hole PCH2. For example, the second pad contact hole PCH2 may extend through the second insulating layer INS2 in the third direction DR3. The second pad PD2 may be exposed to the outside through the second pad contact hole PCH2. The second pad PD2 may overlap the terminal TN of the first circuit board COF.

A non-conductive film NCF may be disposed between the display panel DSP and the first circuit board COF. For example, the non-conductive film NCF may be disposed between the second pads PD2 and the first circuit board COF. The display panel DSP and the first circuit board COF may be bonded to each other by the non-conductive film NCF. The non-conductive film NCF may be made of a material including, for example, resin.

The dummy protrusion pattern DPT may be disposed on the substrate SUB. For example, the dummy protrusion pattern DPT may be disposed between the display panel DSP and the first circuit board COF, in a dummy area DMA between the second pad PD2 and the third side S3 (e.g., the third side S3 of the substrate SUB provided in the display panel DSP) of the display panel DSP. Specifically, the dummy protrusion pattern DPT may be disposed between the substrate SUB of the display panel DSP and the base portion BS of the first circuit board COF, in the dummy area DMA of the display panel DSP (or the substrate SUB). The dummy protrusion pattern DPT may be disposed between the substrate SUB and the base portion BS in the dummy area DMA. The dummy protrusion pattern DPT may be disposed on the first insulating layer INS1, and the second insulating layer INS2 may be disposed on the dummy protrusion pattern DPT. For example, the dummy protrusion pattern DPT may be disposed between the first insulating layer INS1 and the second insulating layer INS2 in the dummy area DMA. The dummy protrusion pattern DPT may be surrounded by the first insulating layer INS1 and the second insulating layer INS2 in the dummy area DMA.

In plan view as illustrated in FIG. 3, the dummy protrusion pattern DPT may have a different size than a protrusion pattern PT. For example, in plan view, an area of the dummy protrusion pattern DPT may be larger than an area of the protrusion pattern PT. However, the present disclosure is not limited thereto, and the area of the dummy protrusion pattern DPT may be the same or smaller than the area of the protrusion pattern PT. Here, the area may mean the size in the first direction DR1 and the second direction DR2.

In plan view as illustrated in FIG. 3, the dummy protrusion pattern DPT may have a quadrilateral shape. However, the present disclosure is not limited thereto., and the dummy protrusion pattern DPT may have various shapes such as a triangular shape, a circular shape and the like.

The dummy protrusion pattern DPT may be formed of the same material as the protrusion pattern PT. For example, the dummy protrusion pattern DPT may include a polymer-based material. Examples of the polymer-based material may include acrylic resin, epoxy resin, polyimide, and polyethylene.

The dummy protrusion pattern DPT may prevent the first circuit board COF and the edge of the display panel DSP from being in contact with each other. For example, in the dummy area DMA of the display panel DSP, the edge of the display panel DSP adjacent to the third side S3 and the base portion BS of the first circuit board COF may be prevented from being in contact with each other. In other words, the dummy protrusion pattern DPT may support the first circuit board COF (e.g., the base portion BS of the first circuit board COF) disposed on the dummy protrusion pattern DPT in the dummy area DMA, thereby preventing the first circuit board COF and the edge of the display panel DSP from contacting each other. The first circuit board COF contacting the edge of the display panel DSP during the attaching of the first circuit board COF and the display panel DSP may result in various issues such as damage to the first circuit board COF, a line crack in the first circuit board COF, or damage to the display panel DSP. These issues may be reduced or minimized by using the dummy protrusion pattern DPT to prevent the first circuit board COF from contacting the edge of the display panel DSP. For example, heat and pressure may be applied to the base portion BS of the first circuit board COF during the process of attaching the first circuit board COF and the display panel DSP. During this attaching process, a gap may be maintained between the display panel DSP (e.g., the substrate SUB of the display panel DSP) and the first circuit board COF (e.g., the base portion BS of the first circuit board COF) in the dummy area DMA by the dummy protrusion pattern DPT. The gap helps avoid the first circuit board COF from contacting the display panel DSP, thereby reducing or preventing the undesirable issues described above.

The cross-sectional structure of the first pad PD1 described above may be substantially the same as the cross-sectional structure of second pad PD2 described above in reference to FIG. 4. However, the first pad electrode PEa of the first pad PD1 may extend to the display area DA to be connected to the fan-out line FL, and extend to the third side S3 to be connected to a dummy line DML. Here, the fan-out line FL may be connected to the second pad electrode PEb through a contact hole in the first insulating layer INS1. Accordingly, the third pad electrode PEc may be electrically connected to the fan-out line FL through the second pad electrode PEb.

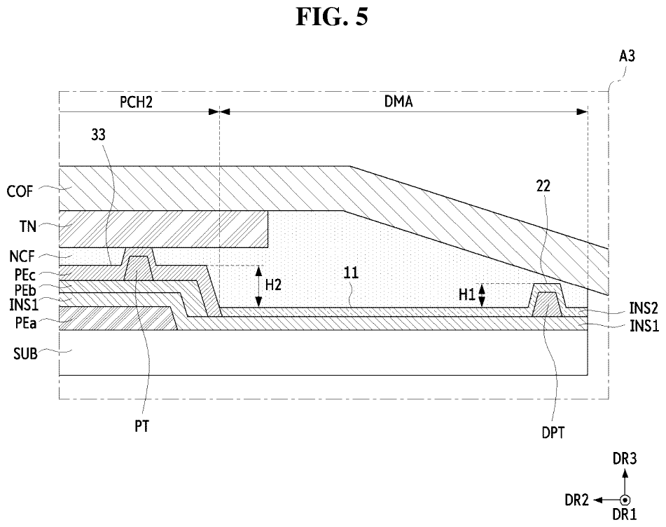

FIG. 5 is an enlarged view of area A3 of FIG. 4.

First, as illustrated in FIG. 5, the portion of the upper surface of the second insulating layer INS2 that does not overlap the dummy protrusion pattern DPT is defined as a first surface 11, the portion of the upper surface of the second insulating layer INS2 that overlaps the dummy protrusion pattern DPT (e.g., a portion of the upper surface of the second insulating layer INS2 disposed on the dummy protrusion pattern DPT) is defined as a second surface 22, and the portion between adjacent protrusion patterns (e.g., the depressions of the third pad electrode PEc) of the upper surface of the third pad electrode PEc is defined as a third surface 33.

, a first height difference H1 between the first surface 11 of the second insulating layer INS2 and the second surface 22 of the second insulating layer INS2 may be different from a height difference H2 between the first surface 11 of the second insulating layer INS2 and the third surface 33 of the third pad electrode PEc. For example, the first height difference H1 (or the distance) between the first surface 11 to the second surface 22 measured in the third direction DR3 may be smaller than or the same as the second height difference H2 (or the distance) between the first surface 11 and the third surface 33 measured in the third direction DR3. In other words, the second surface 22 may be lower than or at the same as the height as the third surface 33. As described above, by setting the first height difference H1 to be smaller than or the same as the second height difference H2 between the first surface 11 and the third surface 33, the gap between the display panel DSP and the first circuit board COF in the dummy area DMA may be maintained at an appropriate distance. Accordingly, the contact between the third pad electrode PEc on the protrusion pattern PT and the terminal TN of the first circuit board COF may be improved.

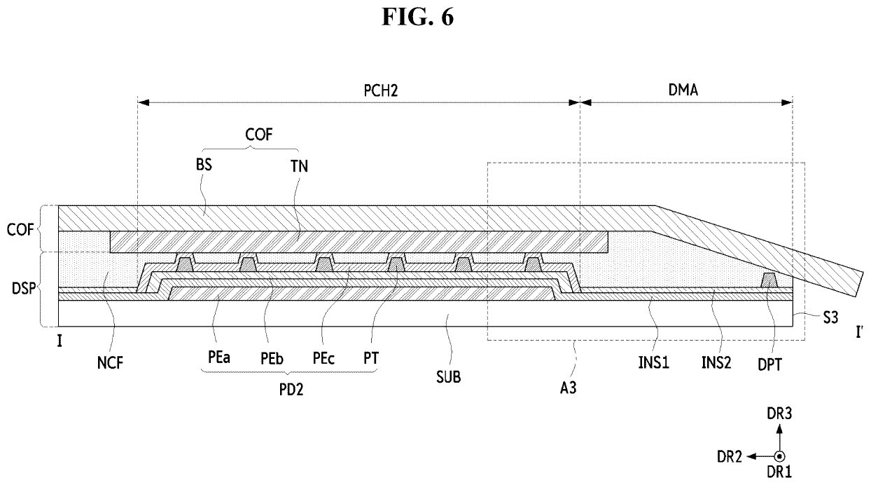

FIG. 6 is a cross-sectional view of a display device 100 according to another embodiment. For example, FIG. 6 may be a cross-sectional view of another embodiment taken along line I-I′ of FIG. 3.

The display device 100 of FIG. 6 is different from the display device 100 of FIG. 4 described above in the location of the dummy protrusion pattern DPT. Therefore, this difference will be mainly described as follows.

As illustrated in FIG. 6, the dummy protrusion pattern DPT may be disposed on the second insulating layer INS2. For example, the dummy protrusion pattern DPT may be disposed between the second insulating layer INS2 and the first circuit board COF. Specifically, the dummy protrusion patter DPT may be disposed between the second insulating layer INS2 and the base portion BS of the first circuit board COF. At this time, the dummy protrusion pattern DPT may be in contact (or in direct contact) with the base portion BS.

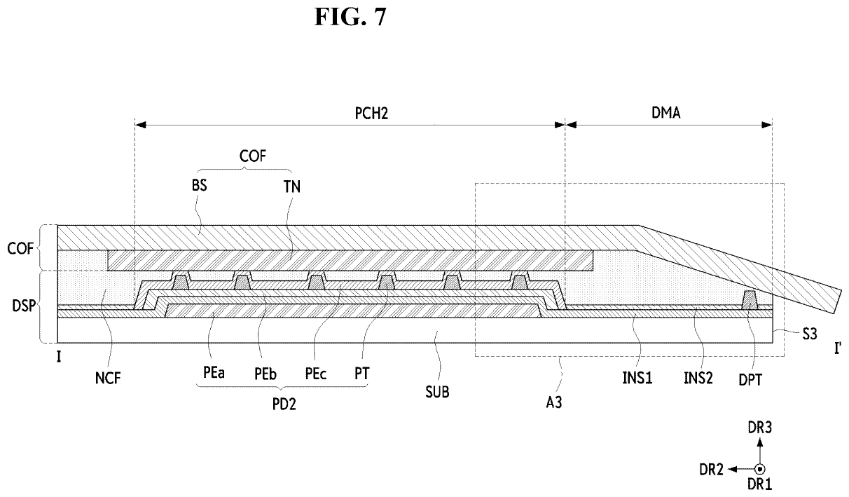

FIG. 7 is a cross-sectional view of a display device 100 according to still another embodiment. For example, FIG. 7 may be a cross-sectional view of still another embodiment taken along line I-I′ of FIG. 3.

The display device 100 of FIG. 7 is different from the display device 100 of FIG. 4 described above in the location of the dummy protrusion pattern DPT. Therefore, this difference will be mainly described as follows.

As illustrated in FIG. 7, the dummy protrusion pattern DPT may be disposed on the first insulating layer INS1. In this embodiment, there is an opening in the second insulating layer INS2, and the dummy protrusion pattern DPT is in that opening. One end of the dummy protrusion pattern DPT may extends into the opening in the second insulating layer INS2 to contact the first insulating layer INS1, and the other end of the dummy protrusion pattern DPT may extend toward the first circuit board COF. The dummy protrusion pattern DPT may be in contact (or in direct contact) with the base portion BS.

At least two or more organic and inorganic layers may be alternately disposed on the dummy protrusion pattern DPT. For example, a first inorganic layer, a first organic layer, and a second inorganic layer may be sequentially disposed between the dummy protrusion pattern DPT and the base portion BS of the first circuit board COF.

A second circuit board PCB may include pads PD connected to other terminals of the first circuit board COF, and the dummy protrusion pattern DPT described above may be disposed at one edge (e.g., one edge overlapping the first circuit board COF) of the second circuit board PCB. In that case, the contact between the second circuit board PCB and the first circuit board COF at one edge of the second circuit board PCB may be minimized by the dummy protrusion pattern DPT.

The display device according to the embodiment can be applied to various electronic devices. The electronic device according to one embodiment includes the display device described above and may further include modules or devices having additional functions in addition to the display device.

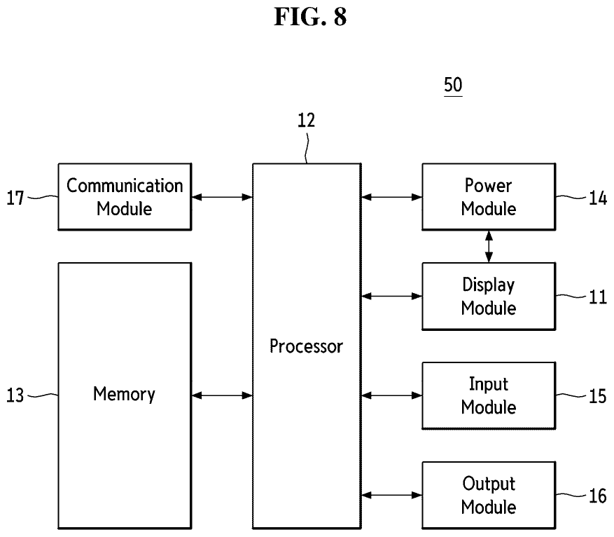

FIG. 8 is a block diagram of an electronic device according to one embodiment. Referring to FIG. 8, the electronic device 50 according to one embodiment may include a display module 11, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 1100, and the processor 12, memory 13, and power module 14 may be provided in the form of other devices within the electronic device 11 other than the display device.

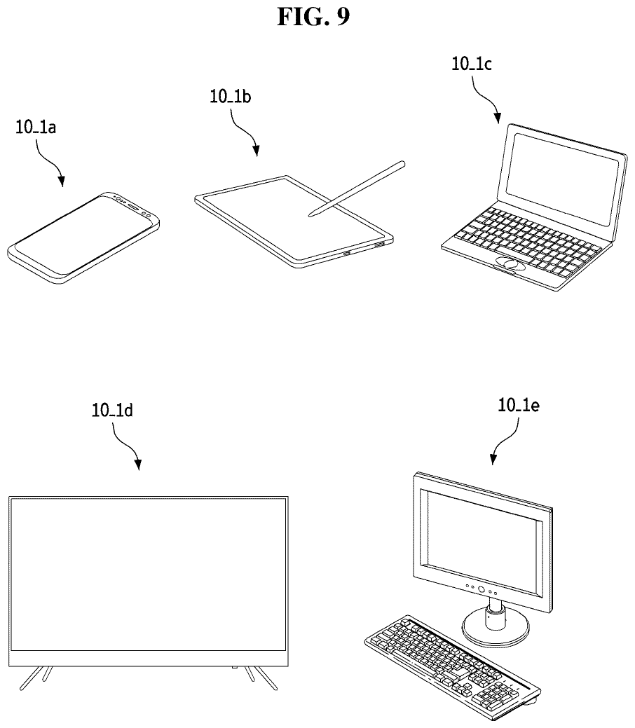

FIGS. 9, 10, and 11 are schematic diagrams of electronic devices according to various embodiments. FIGS. 9 to 11 illustrate examples of various electronic devices to which the display device according to the embodiments is applied.

FIG. 9 illustrates a smartphone 10_1a, a tablet PC 10_1b, a laptop 10_1c, a television 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

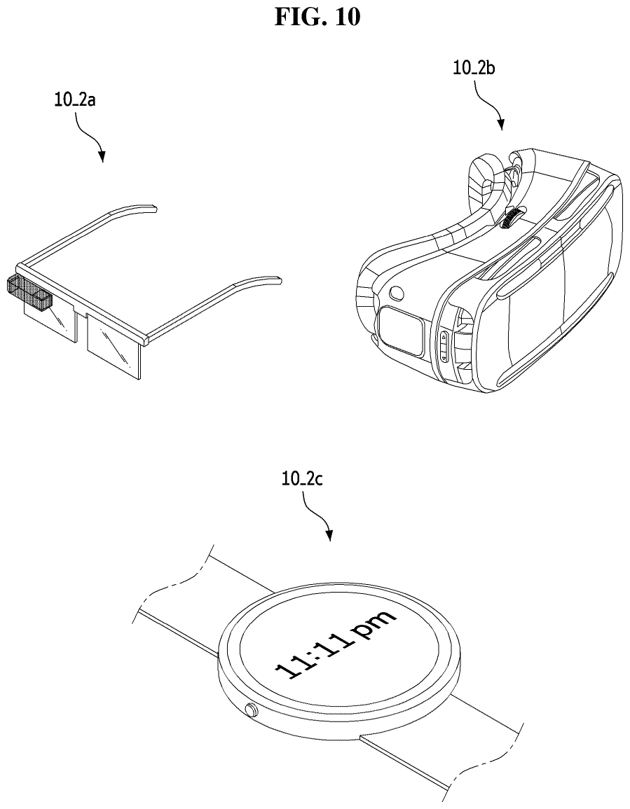

FIG. 10 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display image and provides it to the user's eyes, thereby providing a virtual reality or augmented reality image to the user.

The smart watch 10_2c includes a biometric sensor as an input device, and may provide biometric information recognized by the biometric sensor to the user through the display module.

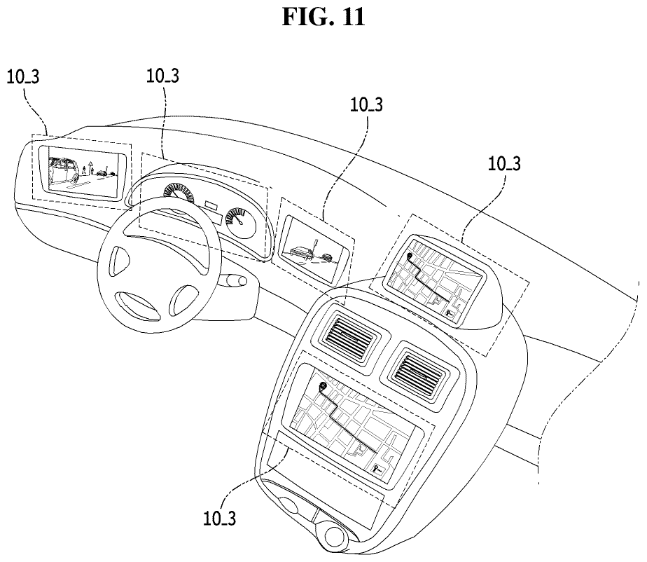

FIG. 11 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel having an edge, a pad, and a dummy area between the edge and the pad;
a first circuit board connected to the pad of the display panel and overlapping the edge of the display panel; and
a dummy protrusion pattern disposed in the dummy area and overlapping the first circuit board.

2. The display device of claim 1,
wherein the first circuit board comprises a base portion and a terminal on the base portion, and
the dummy protrusion pattern overlaps the base portion of the first circuit board.

3. The display device of claim 1,
wherein the display panel comprises:
a substrate;
a first insulating layer on the substrate; and
a second insulating layer on the first insulating layer.

4. The display device of claim 3,
wherein the dummy protrusion pattern is disposed on the first insulating layer in the dummy area.

5. The display device of claim 4,
wherein the dummy protrusion pattern is disposed between the first insulating layer and the second insulating layer in the dummy area.

6. The display device of claim 4,
wherein the dummy protrusion pattern is surrounded by the first insulating layer and the second insulating layer in the dummy area.

7. The display device of claim 3,
wherein the dummy protrusion pattern is disposed on the second insulating layer in the dummy area.

8. The display device of claim 3,
wherein the dummy protrusion pattern is disposed on the first insulating layer and in an opening in the second insulating layer in the dummy area and extends toward the first circuit board.

9. The display device of claim 1,
wherein the pad is a dummy pad.

10. The display device of claim 1,
wherein the pad comprises a protrusion pattern overlapping a terminal of the first circuit board.

11. The display device of claim 10,
wherein the dummy protrusion pattern includes the same material as the protrusion pattern.

12. The display device of claim 11,
wherein each of the dummy protrusion pattern and the protrusion pattern includes a polymer.

13. The display device of claim 10,
wherein, in plan view, the area of the dummy protrusion pattern and the area of the protrusion pattern are different.

14. The display device of claim 10,
wherein, in plan view, the dummy protrusion pattern and the protrusion pattern have similar shapes.

15. The display device of claim 14,
wherein, in plan view, each of the dummy protrusion pattern and the protrusion pattern has a quadrilateral shape.

16. The display device of claim 10,
wherein the pad further comprises:
a first pad electrode disposed on the substrate of the display panel;
a second pad electrode on the first pad electrode; and
a third pad electrode on the second pad electrode and the protrusion pattern.

17. The display device of claim 16, further comprising:
a first insulating layer between the first pad electrode and the second pad electrode; and
a second insulating layer disposed on the first insulating layer and having a pad contact hole exposing the pad.

18. The display device of claim 17,
wherein a portion of the upper surface of the second insulating layer not overlapping the dummy protrusion pattern is defined as a first surface, a portion of the upper surface of the second insulating layer overlapping the dummy protrusion pattern is defined as a second surface, and a portion of the upper surface of the third pad electrode between the adjacent protrusion patterns is defined as a third surface, and
a first height difference between the first surface and the second surface is smaller than or the same as a second height difference between the first surface and the third surface.

19. The display device of claim 1, further comprising a second circuit board connected to the first circuit board.

20. An electronic device comprising:
a memory;
a processor executing an application stored in the memory; and
a display module that includes:
a display panel having an edge, a pad, and a dummy area between the edge and the pad;
a first circuit board connected to the pad of the display panel and overlapping the edge of the display panel; and
a dummy protrusion pattern disposed in the dummy area and overlapping the first circuit board.
